(19) United States
(12) Patent Application Publication
(10) Pub. No.: US 2025/0274104 A1
(43) Pub. Date: Aug. 28, 2025

(54) DUAL-MODE SURFACE ACOUSTICWAVE RESONATOR

(71) Applicant: WISOL CO., LTD., Gyeonggi-do (KR)

(72) Inventor: Jin Hong JEONG, Gyeonggi-do (KR)

(21) Appl. No.: 19/051,609

(22) Filed: Feb. 12, 2025

(30) Foreign Application Priority Data
Feb. 22, 2024 (KR) 10-2024-0025644

(51) Int. Cl. H03H 9/64

(52) U.S. Cl. CPC H03H 9/6473

(57) ABSTRACT

A dual-mode SAW resonator constituting a receiver filter according to the present invention includes a first resonator and a second resonator, each being comprised of a plurality of interdigital transducer (IDT) elements; a signal metal pattern connecting signal terminals formed on the plurality of IDT elements; a ground metal pattern connecting ground terminals formed on the above plurality of IDT elements; and a single insulating film configured to insulate the signal metal pattern from the ground metal pattern, wherein the first resonator and the second resonator are connected in series.

### CROSS-REFERENCE TO RELATED APPLICATION

This application claims priority from Korean Patent Application No. 10-2024-0025644 filed on Feb. 22, 2024 in the Korean Intellectual Property Office, the contents of which in its entirety are herein incorporated by reference.

### FIELD

The present invention relates to a resonator used for communication in a radio frequency (RF) band, and more specifically, to a dual-mode surface acoustic wave (SAW) resonator.

### BACKGROUND

Wireless mobile communication technology requires a variety of radio frequency (RF) components capable of efficiently transmitting information within a limited frequency band. In particular, among the RF components, a filter, which is one of the key components used in mobile communication technology, enables high-quality communication by selecting the signal required by a user from multiple frequency bands or by filtering the signal intended for transmission.

Currently, the RF filters most widely used for wireless communication are dielectric filters and surface acoustic wave (SAW) filters. Dielectric filters are advantages such as high dielectric permittivity, low insertion loss, stability at high temperatures, and high resistance to vibration and shock. However, dielectric filters face limitations in terms of miniaturization and integration into monolithic microwave integrated circuits (MMICs), which are recent trends in technological development. In addition, compared to dielectric filters, SAW filters are compact, facilitate easier signal processing, and have simpler circuitry; furthermore, by employing semiconductor processes, they offer the advantage of mass production. Moreover, SAW filters exhibit higher side rejection within the passband compared to dielectric filters, which enables the transmission and reception of high-quality information.

However, in the case of dual-mode SAW resonators which are used to form a receiver filter including two series resonators, there is a spacing between the two series resonators that limits the ability to minimize the size of the receiver filter.

### SUMMARY

An objective of the present invention is to provide a dual-mode surface acoustic wave (SAW) resonator that enables the reduction of the size of a receiver filter.

According to an aspect of the present invention, there is provided a dual-mode surface acoustic wave (SAW) resonator constituting a receiver filter, the dual-mode saw resonator including: a first resonator and a second resonator, each being comprised of a plurality of interdigital transducer (IDT) elements; a signal metal pattern connecting signal terminals formed on the plurality of IDT elements; a ground metal pattern connecting ground terminals formed on the above plurality of IDT elements; and a single insulating film configured to insulate the signal metal pattern from the ground metal pattern, wherein the first resonator and the second resonator are connected in series.

The signal metal pattern may connect each of the signal terminals through a metal pattern formed between the first resonator and the second resonator.

The ground metal pattern may connect each of the ground terminals through a metal pattern formed between the first resonator and the second resonator.

The insulating film may be arranged between the signal metal pattern and the ground metal pattern.

The insulating film may have insulating film hollow holes formed at positions corresponding to each of the grounding terminals, a portion of a terminal surface of the ground terminal may be exposed through the insulating film hollow holes, and the ground metal pattern may be connected to the exposed ground terminals.

### Effects of the Invention

According to the present invention, by forming a single insulating film between a signal metal pattern, which connects signal terminals formed on each of a plurality of interdigital transducer (IDT) elements, and a ground metal pattern, which connects ground terminals, in a dual-mode surface acoustic wave (SAW) resonator constituting a receiver filter, the size of the dual-mode SAW resonator can be minimized as much as possible, thereby enabling the miniaturization of the receiver filter.

### BRIEF DESCRIPTION OF THE DRAWINGS

FIG. 1 is a circuit diagram of a dual-mode surface acoustic wave (SAW) resonator according to the present invention.

FIG. 2A is a top plan view of a dual-mode SAW resonator according to one embodiment of the present invention.

FIG. 2B is a bottom plan view of the dual-mode SAW resonator shown in FIG. 2A.

FIG. 3 is a reference diagram for comparing the dual-mode SAW resonator according to the present invention with a prior art.

### DETAILED DESCRIPTION

Hereinafter, exemplary embodiments of the present invention will be described in detail with reference to the accompanying drawings.

The embodiments of the present invention are provided to more completely explain the present invention to one of ordinary skill in the art. The embodiments of the present invention may be changed in a variety of shapes, and the scope of the present invention is not limited to the following embodiments. Rather, these embodiments are provided to make the present disclosure more substantial and complete and to completely transfer the concept of the present invention to those skilled in the art.

The terms used herein are to explain particular embodiments and not intended to limit the present invention. As used herein, singular forms may include plural forms unless particularly defined otherwise in context. Also, as used herein, the term “and/or” includes any and all combinations or one of a plurality of associated listed items. In addition, hereinafter, the embodiments of the present invention will be described with reference to the drawings which schematically illustrate the embodiments of the present invention.

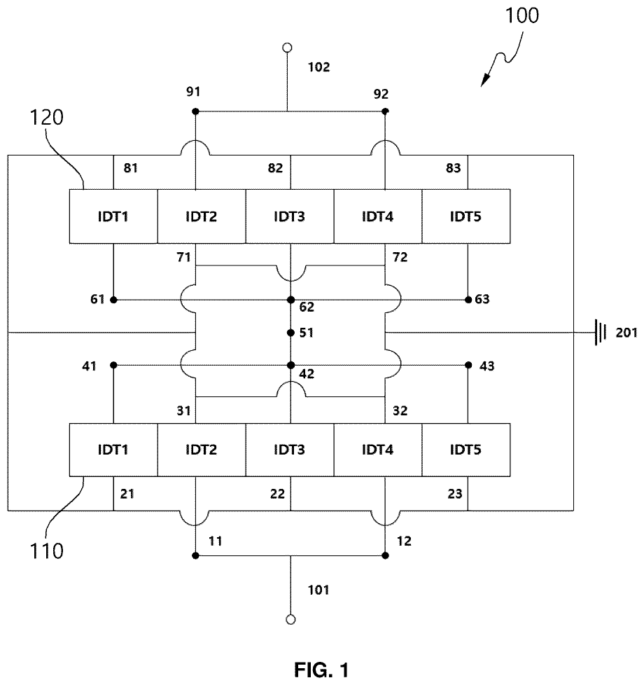

FIG. 1 is a circuit diagram of a dual-mode surface acoustic wave (SAW) resonator 100 according to the present invention.

Referring to FIG. 1, signal wiring 11 and 12 is formed between reference numeral 101 and a first resonator 110, and ground wiring 21, 22, and 23 is formed between reference numeral 101 and the first resonator 110. In addition, the first resonator 110 and a second resonator 120 are connected in series.

Furthermore, signal wiring 41, 42, and 43 is formed for signals transmitted from the first resonator 110 to the second resonator 120, and ground wiring 31, 32, 71, and 72 is formed between the first resonator 110 and the second resonator 120. Also, signal wiring 61, 62, and 63 is formed for the signals input from the first resonator 110 to the second resonator 120.

Reference numerals 41, 42, and 43 denote signal lines coming out of the first resonator 110, while reference numerals 61, 62, and 63 denote signal lines coming out of the second resonator 120.

Moreover, common signal wiring 51 is formed between the first resonator 110 and the second resonator 120.

Additionally, ground wiring 81, 82, and 83 is formed between reference numeral 102 and the second resonator 120, and signal wiring 91 and 92 is formed between reference numeral 102 and the second resonator 120.

Furthermore, common signal wiring 41, 42, 43, 61, 62, and 63 is formed to connect the signal terminals of the first resonator 110 and the second resonator 120, and common ground wiring 31, 32, 71, and 72 is formed to connect the ground terminals of the first resonator 110 and the second resonator 120. Here, reference numeral 201 denotes ground.

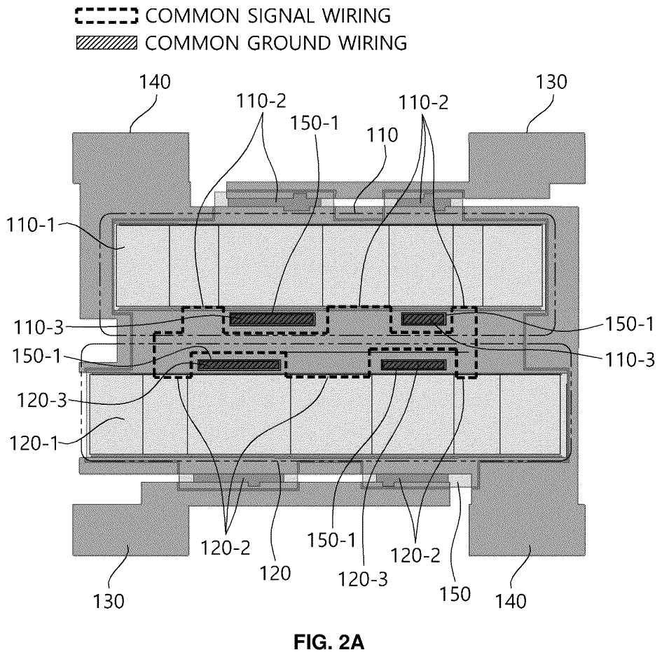

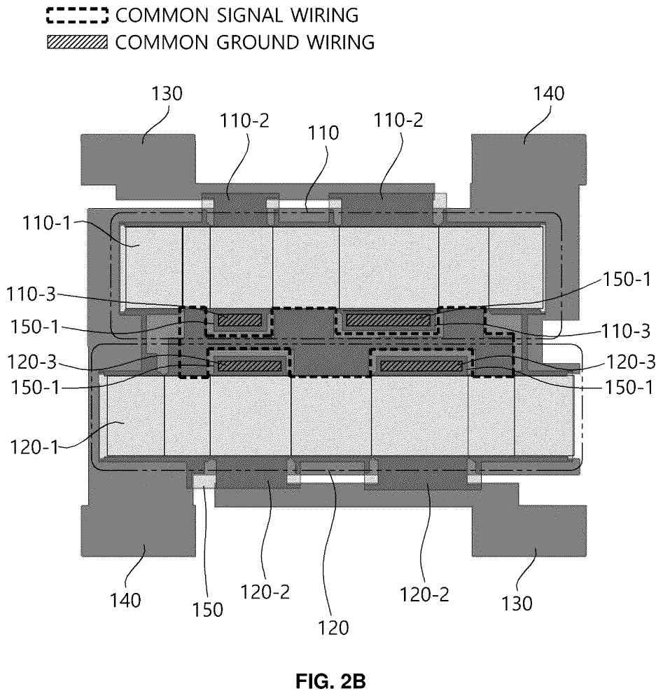

FIG. 2A is a top plan view of a dual-mode SAW resonator according to one embodiment of the present invention, and FIG. 2B is a bottom plan view of the dual-mode SAW resonator shown in FIG. 2A.

Referring to FIGS. 2A and 2B, the dual-mode SAW resonator 100 includes a first resonator 110, a second resonator 120, a signal metal pattern 130, a ground metal pattern 140, and an insulating film 150.

The first resonator 110 is composed of a plurality of interdigital transducer (IDT) elements 110-1. The plurality of IDT elements 110-1 have a plurality of signal terminals 110-2 and ground terminals 110-3 formed thereon.

In addition, the second resonator 120 is composed of a plurality of IDT elements 120-1. The plurality of IDT elements 120-1 have a plurality of signal terminals 120-2 and ground terminals 120-3 formed thereon.

The signal metal pattern 130 interconnects the signal terminals 110-2 formed on the plurality of IDT elements 110-1 in the first resonator 110. In addition, the signal metal pattern 130 interconnects the signal terminals 120-2 formed on the plurality of IDT elements 120-1 in the second resonator 120.

Moreover, the signal metal pattern 130 forms common signal wiring by means of a metal pattern that interconnects the signal terminals 110-2 of the first resonator 110 and the signal terminals 120-2 of the second resonator 120.

Referring to common signal wiring in FIGS. 2A and 2B, the signal metal pattern 130 interconnects the signal terminals 110-2 of the first resonator 110 and the signal terminals 120-2 of the second resonator 120 via the metal pattern formed between the first resonator 110 and the second resonator 120.

The material used for the signal metal pattern 130 is a conventional conductive material such as a metal, and preferably, one of copper (Cu), aluminum (Al), tungsten (W), gold (Au), platinum (Pt), nickel (Ni), titanium (Ti), chromium (Cr), palladium (Pd), ruthenium (Ru), rhenium (Re), or molybdenum (Mo) may be used.

The ground metal pattern 140 interconnects ground terminals 110-3 formed on the plurality of IDT elements 110-1 in the first resonator 110. In addition, the ground metal pattern 140 interconnects ground terminals 120-3 formed on the plurality of IDT elements 120-1 in the second resonator 120.

Moreover, the ground metal pattern 140 forms common ground wiring by means of a metal pattern that interconnects the ground terminals 110-3 of the first resonator 110 and the ground terminals 120-3 of the second resonator 120.

Referring to common ground wiring in FIGS. 2A and 2B, the ground metal pattern 140 interconnects the ground terminals 110-3 of the first resonator 110 and the ground terminals 120-3 of the second resonator 120 via the metal pattern formed between the first resonator 110 and the second resonator 120.

The material used for the ground metal pattern 140 is a conventional conductive material such as a metal, and preferably, one of copper (Cu), aluminum (Al), tungsten (W), gold (Au), platinum (Pt), nickel (Ni), titanium (Ti), chromium (Cr), palladium (Pd), ruthenium (Ru), rhenium (Re), or molybdenum (Mo) may be used.

The insulating film 150 insulates the signal metal pattern 130 from the ground metal pattern 140. The insulating film 150 has a single film structure for insulating the signal metal pattern 130 from the ground metal pattern 140. The insulating film 150 is arranged between the signal metal pattern 130 and the ground metal pattern 140. In other words, the dual-mode SAW resonator 100 is structured such that the insulating film 150 is formed on top of the signal metal pattern 130 and the ground metal pattern 140 is formed on top of the insulating film 150.

The insulating film 150 has insulating film hollow holes 150-1 formed at positions corresponding to the ground terminals 110-3 of the first resonator 110 and the ground terminals 120-3 of the second resonator 120.

At this time, a portion of a terminal surface of each of the ground terminals 110-3 of the first resonator 110 and a portion of a terminal surface of each of the ground terminals 120-3 of the second resonator 120 are exposed through the insulating film hollow holes 150-1.

Accordingly, although the signal terminals 110-2 of the first resonator 110 and the signal terminals 120-2 of the second resonator 120 are insulated from the ground metal pattern 140 by the insulating film 150, the ground terminals 110-3 of the first resonator 110 and the ground terminals 120-3 of the second resonator 120 have portions of their surfaces exposed through the insulating film hollow holes 150-1. Thus, the ground metal pattern 140 formed on top of the insulating film 150 may be connected to the exposed ground terminals 120-3.

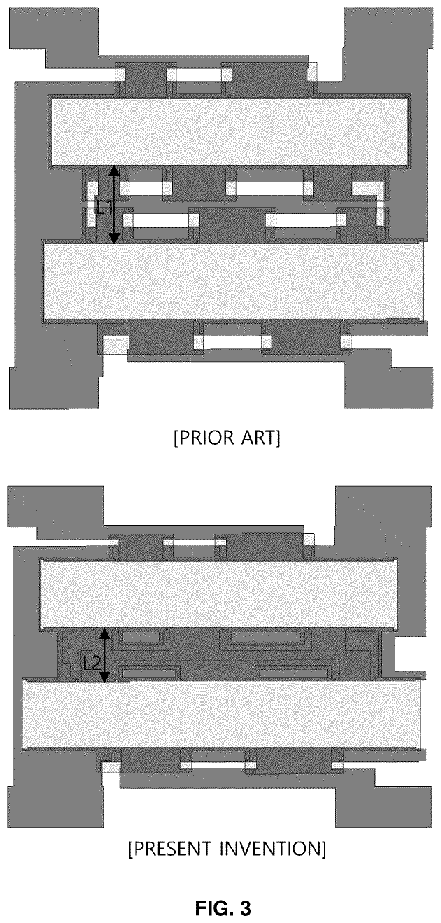

FIG. 3 is a reference diagram for comparing the dual-mode SAW resonator according to the present invention with a prior art.

Referring to FIG. 3, in the case of a dual-mode SAW resonator according to a prior art, ground terminals that constitute first and second resonators must be spaced apart, and a common signal pattern must be arranged between them, so a distance L1 between the first and second resonators must be at least a certain distance (for example, 110 to 120 [μm]). However, in the dual-mode SAW resonator of the present invention, by forming a single insulating film between the signal metal pattern and the ground metal pattern of the first and second resonators, a distance L2 between the first and second resonators may be minimized to a reduced distance (for example, 60 to 70 [μm]), unlike in the prior art.

Thus, since the distance L2 between the first and second resonators in the present invention is reduced compared to the distance L1 in the prior art, miniaturization of the dual-mode SAW resonator 100 may be realized.

The exemplary embodiments of the present invention have been described above. One of ordinary skill in the art may understand that modifications may be made without departing from the scope of the present invention. Therefore, the disclosed embodiments should be considered in a descriptive aspect not a limitative aspect. The scope of the present invention will be shown in the claims not in the foregoing description, and all differences within an equivalent scope thereof should be construed as being included in the present invention.

### REFERENCE NUMERALS

100: DUAL-MODE SAW RESONATOR
110: FIRST RESONATOR
120: SECOND RESONATOR
130: SIGNAL METAL PATTERN
140: GROUND METAL PATTERN
150: INSULATING FILM

What is claimed is:

1. A dual-mode surface acoustic wave (SAW) resonator constituting a receiver filter, the dual-mode saw resonator comprising:
a first resonator and a second resonator, each being comprised of a plurality of interdigital transducer (IDT) elements;
a signal metal pattern connecting signal terminals formed on the plurality of IDT elements;
a ground metal pattern connecting ground terminals formed on the above plurality of IDT elements; and
a single insulating film configured to insulate the signal metal pattern from the ground metal pattern,
wherein the first resonator and the second resonator are connected in series.

2. The dual-mode SAW resonator of claim 1, wherein the signal metal pattern connects each of the signal terminals through a metal pattern formed between the first resonator and the second resonator.

3. The dual-mode SAW resonator of claim 1, wherein the ground metal pattern connects each of the ground terminals through a metal pattern formed between the first resonator and the second resonator.

4. The dual-mode SAW resonator of claim 1, wherein the insulating film is arranged between the signal metal pattern and the ground metal pattern.

5. The dual-mode SAW resonator of claim 4, wherein the insulating film has insulating film hollow holes formed at positions corresponding to each of the grounding terminals, a portion of a terminal surface of the ground terminal is exposed through the insulating film hollow holes, and the ground metal pattern is connected to the exposed ground terminals.
